(19) United States
(12) Patent Application Publication
(10) Pub. No.: US 2021/0398774 A1
(43) Pub. Date: Dec. 23, 2021

(54) ETCHING DEVICE AND METHOD OF INDUCTIVELY COUPLED PLASMA

(71) Applicant: JIANGSU LEUVEN INSTRUMENTS CO. LTD, Xuzhou (CN)

(72) Inventors: Xiaobo LIU, Xuzhou (CN); Xuedong LI, Xuzhou (CN); Dongdong HU, Xuzhou (CN); Dongchen CHE, Xuzhou (CN); Jia WANG, Xuzhou (CN); Lu CHEN, Xuzhou (CN); Kangning XU, Xuzhou (CN); Kaidong XU, Xuzhou (CN)

(21) Appl. No.: 17/287,791

(22) PCT Filed: Aug. 21, 2019
(86) PCT No.: PCT/CN2019/101726

§ 371 Date: Apr. 22, 2021

(30) Foreign Application Priority Data
Oct. 24, 2018 (CN) 201811246568.6

(51) Int. Cl. H01J 37/32; H01L 43/12; H01L 21/311

(52) U.S. Cl. CPC H01J 37/321; H01J 37/32183; H01J 2237/334; H01L 21/31116; H01L 43/12

(57) ABSTRACT

An etching device and method of inductively coupled plasma. The etching device of inductively coupled plasma includes an etching chamber, an excitation radio-frequency power supply, and a first bias radio-frequency power supply, and further includes a second bias radio-frequency power supply. The frequency of the second bias radio-frequency power supply is significantly lower than that of the first bias radio-frequency power supply. The etching rate and angle are controllable by means of the process of controlling distribution of ion energy by adjusting the radio-frequency bias of different frequencies, so as to adjust etching. In addition, since the mean free path of ions is larger, and the power utilization rate of etching is higher at the low pressure and low bias radio-frequency frequencies, rapid etching is achieved at relatively low power to implement green and energy-saving processing. The disclosure is applicable to the etching of magnetic tunnel junctions.

### BACKGROUND OF THE INVENTION

### Field of the Invention

The present invention relates to the field of semiconductor technologies, and in particular, to an etching device and method of inductively coupled plasma.

### Description of Related Art

As the feature size of semiconductor devices is further reduced, the conventional flash memory technology will reach the limit determined by the physical properties of the material. In order to further improve the device performance, research and development personnel begin to actively explore new structures, new materials, and new processes. In recent years, various types of novel non-volatile memories have developed rapidly. Among these memories, a magnetic random-access memory (MRAM) has a high-speed read/write capability of a static random access memory (SRAM), high integration of a dynamic random access memory (DRAM), and power consumption far lower than that of the DRAM; and its performance does not degrade with the use time as compared with a flash memory (Flash). Due to these advantages, the MRAM gets more and more attention from the industry and is regarded as one of the powerful candidates for the next generation of “general-purpose” memory that is very likely to replace the SRAM, DRAM, and Flash. The industry and research institutions are committed to optimizing the circuit design, process methods, and integration solutions so as to obtain MRAM devices which can be successfully commercialized.

As a core structure of the MRAM, a magnetic tunnel junction (MTJ) is composed of a fixed layer, a non-magnetic isolation layer, and a free layer. The fixed layer is relatively thick; and has strong magnetism and magnetic torque which is not easily reversed. The free layer is relatively thin; and has weak magnetism and easily reversed magnetic torque. According to parallel and antiparallel variation in magnetic moment between the free layer and the fixed layer, a status shown as “0” or “1” is output.

The conventional etching of large-size MTJs is generally realized by means of ion beam etching. Because inert gas is used in ion beam etching, basically no chemical etching component is introduced into a reaction chamber, so that sidewalls of the MTJ are protected from chemical erosion. However, when the size of a magnetic memory device is below 80 nm, especially, when a dot pitch is less than 120 nm, it is rather difficult to realize complete and damage-free separation of the device merely by ion beam etching. Therefore, a reactive-ion plasma etching chamber gradually gets attention from the memory industry and related research has been conducted. Magnetic materials, transition metal materials, and the like that are widely used in the MTJ are difficult to react with known chemical gas to form volatile gas that can be removed by a vacuum pump. Therefore, MTJ etching based on the reactive-ion plasma etching chamber relies heavily on the etching principle of physical bombardment. In other words, during etching of the magnetic materials and transition metal materials, films are bombarded by a physical force and the materials are pumped away from the films with the vacuum pump, thus completing etching. Such a process requires a variable magnitude of the physical force in the reactive-ion etching chamber and a controllable force distribution range. The conventional reactive-ion etching apparatus generally uses a power frequency above 1 MHz and thus is unable to provide a relatively large physical force. Consequently, the reactive-ion etching chamber has an insufficient ability to etch the MTJ, affecting the performance of an etched device and the productivity of the etching apparatus.

### SUMMARY OF THE INVENTION

To solve the foregoing problems, the present invention discloses an etching device of inductively coupled plasma, which includes an etching chamber, an excitation radio-frequency power supply, and a first bias radio-frequency power supply; and further includes a second bias radio-frequency power supply, where the frequency of the second bias radio-frequency power supply is significantly lower than that of the first bias radio-frequency power supply.

In the etching device of inductively coupled plasma of the present invention, preferably, the frequency of the first bias radio-frequency power supply is 13.56 MHz, 27.12 MHz, or 40.68 MHz.

In the etching device of inductively coupled plasma of the present invention, preferably, the frequency of the second bias radio-frequency power supply ranges from 200 kHz to 500 kHz and its power ranges from 10 W to 2000 W.

In the etching device of inductively coupled plasma of the present invention, preferably, the frequency of the second bias radio-frequency power supply ranges from 1.7 MHz to 2.3 MHz and its power ranges from 10 W to 1000 W.

In the etching device of inductively coupled plasma of the present invention, preferably, the excitation radio-frequency power supply is connected to a top electrode of the etching chamber; and the first bias radio-frequency power supply and the second bias radio-frequency power supply are separately connected to a bottom electrode of the etching chamber via a switch.

In the etching device of inductively coupled plasma of the present invention, preferably, in an etching process, the excitation radio-frequency power supply is in an on state, and one of the first bias radio-frequency power supply and the second bias radio-frequency power supply is turned on.

In the etching device of inductively coupled plasma of the present invention, preferably, the excitation radio-frequency power supply is connected to a top electrode of the etching chamber, the first bias radio-frequency power supply is connected to a bottom electrode of the etching chamber via a high-pass filter, and the second bias radio-frequency power supply is connected to the bottom electrode of the etching chamber via a low-pass filter.

In the etching device of inductively coupled plasma of the present invention, preferably, in an etching process, the excitation radio-frequency power supply is in an on state; and one of the first bias radio-frequency power supply and the second bias radio-frequency power supply is turned on or both of the two are turned on simultaneously.

The present invention further discloses an etching method of inductively coupled plasma, where in an etching process, the excitation radio-frequency power supply is turned on; and at least one of the first bias radio-frequency power supply and the second bias radio-frequency power supply is turned on according to process requirements.

In the etching method of inductively coupled plasma of the present invention, preferably, the method for etching inductively coupled plasma is applicable to MTJ etching.

### BRIEF DESCRIPTION OF THE DRAWINGS

FIG. 1 shows numerical simulation results of an ion energy distribution function in a single sheath layer at different frequencies during current-driven nitrogen discharge;

FIG. 2 is a schematic configuration diagram of radio-frequency power supplies in an embodiment of an etching device of inductively coupled plasma;

FIG. 3 is a schematic configuration diagram of radio-frequency power supplies in another embodiment of an etching device of inductively coupled plasma; and

FIG. 4 shows curves of forward transmission coefficients on opposite circuits respectively at a test point T1 on a branch of a first bias radio-frequency power supply in (a) and a test point T2 on a branch of a second bias radio-frequency power supply in (b) when the first and second bias radio-frequency power supplies are simultaneously tuned on.

### DETAILED DESCRIPTION OF THE INVENTION

To make the objective, technical solutions, and advantages of the present invention clearer, the technical solutions in the embodiments of the present invention are clearly and completely described below with reference to the accompanying drawings in the embodiments of the present invention. It should be noted that, the specific embodiments described herein are merely used for explaining the present invention, rather than limiting the present invention. The described embodiments are some rather than all of the embodiments of the present invention. Based on the described embodiments of the present invention, other embodiments acquired by those of ordinary skill in the art without creative effort all belong to the protection scope of the present invention.

An etching device of inductively coupled plasma in the present invention includes an etching chamber, an excitation radio-frequency power supply, a first bias radio-frequency power supply, and a second bias radio-frequency power supply, where the frequency of the second bias radio-frequency power supply is significantly lower than that of the first bias radio-frequency power supply. For example, the frequency of the first bias radio-frequency power supply is 13.56 MHz, 27.12 MHz, or 40.68 MHz. Different frequencies may be selected for the second bias radio-frequency power supply according to different etched patterns, and there are usually two frequency bands for selection: The frequency of the second bias radio-frequency power supply ranges from 350 kHz to 450 kHz and its power ranges from 10 W to 2000 W; or the frequency of the second bias radio-frequency power supply ranges from 1.7 MHz to 2.3 MHz and its power ranges from 10 W to 1000 W.

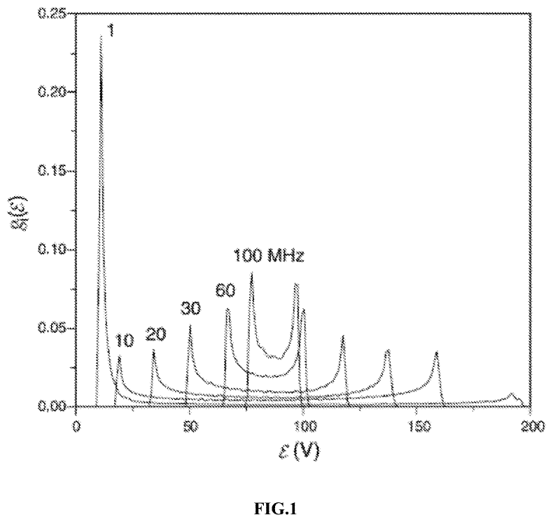

In plasma material processing, ion energy distribution is very important because a substrate surface may be subjected to ion bombardment. Chapter 11 of Principle of Plasma Discharge and Material Processing written by Michal gives numerical simulation results of an ion energy distribution function in a single sheath at different frequencies during current-driven nitrogen discharge, as shown in FIG. 1. At different radio-frequency frequencies, the ion energy on the substrate surface presents a bimodal distribution, and the width between the bimodal peaks gradually widens as the frequency decreases. Correspondingly, the energy of low-energy ions moves in a lower direction, while the energy of high-energy ions becomes higher. Therefore, lowering the radio-frequency frequency will obtain higher-energy ions, which is beneficial for MTJ etching which relies on physical bombardment.

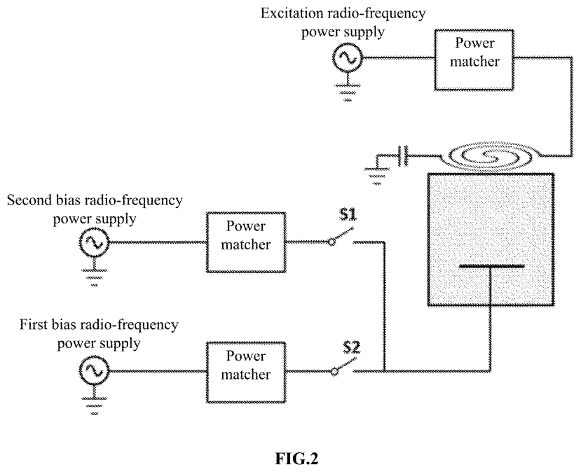

In an embodiment of the etching device of inductively coupled plasma, as shown in FIG. 2, the excitation radio-frequency power supply is connected to a top electrode of the etching chamber, to produce an electromagnetic field by using a radio-frequency current flowing in an inductance coil of the top electrode so as to excite gas ionization. The first bias radio-frequency power supply and the second bias radio-frequency power supply are separately connected to a bottom electrode of the etching chamber via a switch, so as to supply bias energy to the plasma. In an etching process, the excitation radio-frequency power supply is in an on state, and one of the first bias radio-frequency power supply and the second bias radio-frequency power supply is turned on. Further preferably, for the connection between the foregoing different radio-frequency power supplies and the etching chamber, impedance transformation may be performed by using radio-frequency power matchers, so as to maximize transmission of radio-frequency energy.

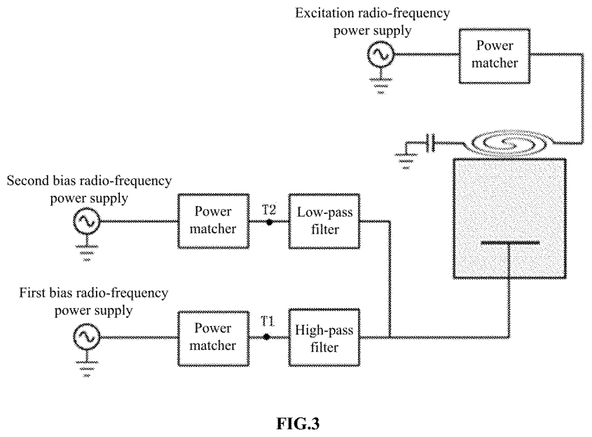

In another embodiment of the etching device of inductively coupled plasma, as shown in FIG. 3, the excitation radio-frequency power supply is connected to a top electrode of the etching chamber, the first bias radio-frequency power supply is connected to a bottom electrode of the etching chamber via a high-pass filter, and the second bias radio-frequency power supply is connected to the bottom electrode of the etching chamber via a low-pass filter. Specifically, the filters use a network of inductors and capacitors to realize impedance transformation at a specified frequency, to achieve power transmission and filtering. For example, a capacitor is used on a series circuit of the high-pass filter to impede passage of low-frequency power, and an inductive voltage divider is used on a parallel circuit to filter out a small amount of low-frequency power that passes through the circuit. An inductor is used on a series circuit of the low-pass filter to impede passage of high-frequency power, and a capacitive voltage divider is used on a parallel circuit to filter out a small amount of high-frequency power that passes through the circuit. In an etching process, the excitation radio-frequency power supply is in an on state, and one of the first bias radio-frequency power supply and the second bias radio-frequency power supply is turned on or both of the two are turned on simultaneously. Further preferably, for the connection between the foregoing different radio-frequency power supplies and the etching chamber, impedance transformation may be performed by using radio-frequency power matchers, so as to maximize transmission of radio-frequency energy.

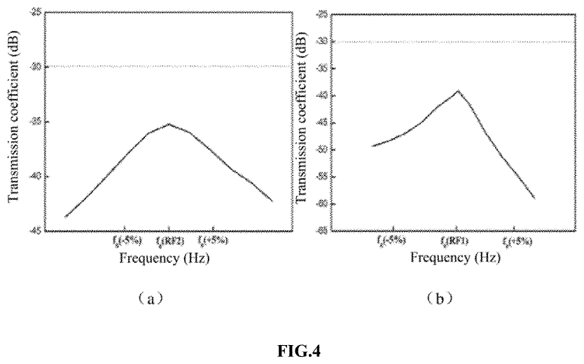

Connection of the low-pass filter to a branch circuit of the second bias radio-frequency power supply can enable passage of the low-frequency radio frequency and reflection of the high-frequency radio frequency. Therefore, the high-frequency radio frequency generated by the first bias radio-frequency power supply cannot pass through the low-pass filter, avoiding crosstalk of the high-frequency radio frequency to a second bias radio-frequency circuit. Moreover, the vast majority of the high-frequency radio frequency can only be transmitted to the bottom electrode, so that the transmission of the radio-frequency energy is maximized. Likewise, the low-frequency radio frequency produced by the second bias radio-frequency power supply also can only be transmitted to the bottom electrode, thus ensuring transmission maximization of the radio-frequency energy and further avoiding crosstalk between the first and second bias radio-frequency power supplies. FIGS. 4 (a) and (b) show curves of forward transmission coefficients S21 obtained respectively at a test point T1 on a branch of the first bias radio-frequency power supply and a test point T2 on a branch of the second bias radio-frequency power supply. A smaller S21 value indicates higher reflectivity and lower transmission efficiency of the radio-frequency energy. On the contrary, a higher S21 value indicates lower reflectivity, lower loss of a radio-frequency transmission network, and higher transmission efficiency of the radio-frequency energy. Generally, S21<−30 dB on a branch can meet the requirements. It can be known from FIG. 4 that, the transmission coefficients on the branches of the first bias radio-frequency power supply and the second bias radio-frequency power supply are both less than −30 dB, which indicates that such a circuit design meets the requirements of actual application.

During etching by using the etching device of inductively coupled plasma of the present invention, an etching gas is introduced after a sample is delivered to a reactive-ion etching chamber, where the used etching gas may be inert gas, nitrogen, oxygen, fluorine-based gas, NH₃, amino gas, CO, CO₂, alcohol, or the like. A gas flow is preferably 5-300 SCCM; and the gas is controlled at a relatively low pressure of, for example, 1-20 mT. The excitation radio-frequency power supply, the first bias radio-frequency power supply, and the second bias radio-frequency power supply are turned on simultaneously, where the excitation radio-frequency power supply has power of 50 W to 300 W, the first bias radio-frequency power supply has a frequency of 13.56 MHz and power of 10 W to 30 W, and the second bias radio-frequency power supply has a frequency of 400 kHz and power of 20 W to 40 W. Definitely, the present invention is not limited thereto, and only the first bias radio-frequency power supply or only the second bias radio-frequency power supply may be turned on according to actual process requirements.

In the plasma, a sheath layer is essential in controlling the movement of ions towards the substrate. Collision and motion of various particles in the sheath layer determine energy distribution and angular distribution of the ions incident on a polar plate, which is significant in terms of ion etching and manufacturing of advanced electronic devices. At a low gas pressure, ions do not experience collision when travelling through the sheath layer; while at a high gas pressure, collision between the ions and neutral particles within the sheath layer strongly affects an ion energy distribution function. At the low gas pressure, the width of the sheath layer is far less than a mean free path of the ions, and therefore, collision is unlikely to occur during the movement of the ions in the sheath layer. In this case, the energy distribution and angular distribution of the ions are almost insusceptible to ion collision in the sheath layer. As the gas pressure in the discharge space decreases, the proportion of high-energy particles in the energy distribution increases and the proportion of charged particles vertically incident on the substrate also increases. Because there is only a distribution of an axial electric field, during ion bombardment to the substrate, higher energy corresponds to a smaller incident angle and more high-energy ions indicate narrower angular distribution. Therefore, by use of a low gas pressure and low second bias radio-frequency frequencies in etching, the present invention increases a mean free path of the plasma, so that the plasma accumulates relatively high energy and rate to vertically bombard the surface of a workpiece to be etched. With a small incident angle, high-energy ions depart from the boundary of the sheath layer, accelerate by passing through a path with a length being the thickness of a photoresist film, and then bombard the surface of a metal film almost vertically with high kinetic energy. Low-energy ions have a relatively large incident angle and most of the ions bombard the photoresist surface without completion of acceleration. Even if some ions reach and bombard the sidewall of the device to be etched, they cannot bring damage to the sidewall due to too low energy.

The etching device and method of inductively coupled plasma of the present invention can control distribution of ion energy by adjusting the radio-frequency bias of different frequencies, so as to adjust the MTJ etching process. The etching is rapid and the anisotropy is weak at a high frequency, while the etching is slow and the anisotropy is strong at a low frequency, so that the etching rate and the damage to the front and sidewall of a produced etched pattern are more controllable. In addition, the present invention can increase the energy of high-energy ions in the plasma and reduce the energy of low-energy ions by means of adjustment, so as to ensure a single wafer bombardment angle, thus effectively reducing physical damage to the MTJ sidewall. In addition, since the mean free path of ions is large and the power utilization rate of etching is high at the low pressure and low bias radio-frequency frequencies, rapid etching is achieved at relatively low power to implement green and energy-saving processing. The present invention is especially applicable to MTJ etching, where the MTJ may have a single isolation layer or multiple isolation layers.

One or both of the two bias radio-frequency power supplies in the present invention may be turned on according to different etched patterns. Usually, in etching of a shallow trench or a trench with a relatively small depth-to-width ratio, the first bias radio-frequency power supply is turned on; or the two bias radio-frequency power supplies are turned on simultaneously, with the first bias radio-frequency power supply as the dominant one due to its relatively high power and the second bias radio-frequency power supply as the auxiliary one due to its relatively low power. In etching of a deep trench or a trench with a relatively large depth-to-width ratio, the second bias radio-frequency power supply is turned on; or the two bias radio-frequency power supplies are turned on simultaneously, with the first bias radio-frequency power supply as the auxiliary one due to its relatively low power and the second bias radio-frequency power supply as the dominant one due to its relatively high power.

The above merely describes specific embodiments of the present invention, but the protection scope of the present invention is not limited thereto. Changes or replacements easily conceived by any person skilled in the art within the technical scope disclosed in the present invention all fall within the protection scope of the present invention.

What is claimed is:

1. An etching device of inductively coupled plasma, comprising an etching chamber, an excitation radio-frequency power supply, and a first bias radio-frequency power supply, wherein
the device further comprises a second bias radio-frequency power supply, and the frequency of the second bias radio-frequency power supply is significantly lower than that of the first bias radio-frequency power supply.

2. The etching device of inductively coupled plasma according to claim 1, wherein
the frequency of the first bias radio-frequency power supply is 13.56 MHz, 27.12 MHz, or 40.68 MHz.

3. The etching device of inductively coupled plasma according to claim 2, wherein
the frequency of the second bias radio-frequency power supply ranges from 200 kHz to 500 kHz and its power ranges from 10 W to 2000 W.

4. The etching device of inductively coupled plasma according to claim 2, wherein
the frequency of the second bias radio-frequency power supply ranges from 1.7 MHz to 2.3 MHz and its power ranges from 10 W to 1000 W.

5. The etching device of inductively coupled plasma according to claim 1, wherein
the excitation radio-frequency power supply is connected to a top electrode of the etching chamber; and the first bias radio-frequency power supply and the second bias radio-frequency power supply are separately connected to a bottom electrode of the etching chamber via a switch.

6. The etching device of inductively coupled plasma according to claim 5, wherein
in an etching process, the excitation radio-frequency power supply is in an on state, and one of the first bias radio-frequency power supply and the second bias radio-frequency power supply is turned on.

7. The etching device of inductively coupled plasma according to claim 1, wherein
the excitation radio-frequency power supply is connected to a top electrode of the etching chamber, the first bias radio-frequency power supply is connected to a bottom electrode of the etching chamber via a high-pass filter, and the second bias radio-frequency power supply is connected to the bottom electrode of the etching chamber via a low-pass filter.

8. The etching device of inductively coupled plasma according to claim 7, wherein
in an etching process, the excitation radio-frequency power supply is in an on state; and one of the first bias radio-frequency power supply and the second bias radio-frequency power supply is turned on or both of the two are turned on simultaneously.

9. An etching method of inductively coupled plasma, which uses etching the device of inductively coupled plasma according to claim 1, wherein
in an etching process, the excitation radio-frequency power supply is turned on; and at least one of the first bias radio-frequency power supply and the second bias radio-frequency power supply is turned on according to process requirements.

10. The etching method of inductively coupled plasma according to claim 9, wherein
the etching method of inductively coupled plasma is applicable to magnetic tunnel junction (MTJ) etching.
